(19) United States
(12) Patent Application Publication
(10) Pub. No.: US 2025/0259864 A1
(43) Pub. Date: Aug. 14, 2025

(54) RAPID THERMAL CYCLING ANNEALING APPARATUS

(71) Applicant: Agnitron Technology, Inc., Chanhassen, MN (US)

(72) Inventors: Aaron Fine, Golden Valley, MN (US); Andrei Osinksy, Chanhassen, MN (US); Evan Buskirk, Maple Grove, MN (US)

(21) Appl. No.: 18/439,678

(22) Filed: Feb. 12, 2024

(51) Int. Cl. H01L 21/67; H01L 21/324

(52) U.S. Cl. CPC H01L 21/67103; H01L 21/324; H01L 21/67109

(57) ABSTRACT

Apparatuses for rapid-cycle high-temperature heating and cooling are disclosed. The apparatuses can be used for elementary, binary, tertiary, and quaternary alloys of wide and ultra-wide band gap compound semiconductors. The apparatuses can be used for wafer annealing, and can include an induction coil, and at least one gas nozzle. A susceptor holds a workpiece with a first face of the workpiece exposed and a second face of the workpiece in thermal contact with a first surface of the susceptor. The first gas nozzle is arranged to disperse cooling gas to the susceptor and workpiece assembly. Each heating operation uses inductive coupling to the susceptor to heat the workpiece from 800° C.-1100° C. to 1400° C.-2500° C. in about one second (for one example). Each cooling operation uses cooling gas dispersion to cool the workpiece from 1400° C.-2500° C. to 800° C.-1100° C. in about one second (for another cooling example).

### BACKGROUND

Annealing is broadly known in materials science as a heat treatment that alters the microstructure of a material. Over the ages annealing has been applied to metallurgy, for example to strengthen blades of various metals, metal gears and other components for machinery, and in more modern times for semiconductor processing specifically to improve selective area doping by electrical activation and removal of post implantation damage. On top of its possible use with improving semiconductors before or after full or partial manufacture of integrated circuits, thus improving reliability, consistency and quality. Many processes and apparatuses for annealing various materials have been developed, for various temperature ranges of heating and cooling, and various cycle counts and duration time spans for heating and cooling cycles. Yet there remain challenges for annealing various materials, particularly for higher temperatures and energy levels that may damage, destroy or just negate the electrical material properties that can happen if the annealing is not done perfectly to spec. Furthermore, these extreme environments and parameters can result in the damaging, destruction, or reduced operating lifespan of the equipment itself. Likewise, there remain challenges to develop higher temperature, higher energy level, shorter cycle time annealing that avoids uneven heating or cooling across a workpiece and avoids damaging or unevenly annealing the workpiece and suboptimal quality. Therefore, there is a need in the art for a solution which overcomes the drawbacks described above. What is sought, and demonstrated herein is a system capable of thermally annealing faster, within a pure environment, with higher uniformity for both heating and cooling than other systems at these rates, and with greater versatility for other materials, gas environments or lower or even higher heating/cooling rates with flow of more cooling air for cooling, or increased power to the heating coils for heating.

### SUMMARY

Various embodiments for rapid-cycle high-temperature heating and cooling are described herein. Embodiments may be operable using a susceptor and a workpiece, which may be a semiconductor wafer.

One embodiment is an apparatus having a susceptor, at least one induction coil, and at least one gas nozzle. The susceptor has a first surface and opposed second surface, arranged to hold a workplace with a first face of the workpiece exposed and a second face of the workpiece in thermal contact with the first surface of the susceptor. Such an assembly is termed a susceptor and workpiece assembly. The induction coil(s) is arranged to receive the susceptor holding the workpiece, with the induction coil(s) in wraparound arrangement to the susceptor and workpiece assembly. At least one gas nozzle is arranged to disperse cooling gas to the susceptor and workpiece assembly. The apparatus is operable to perform a sequence of cycles of heating and cooling operations on the susceptor and workpiece assembly, cycling the workpiece to and from a first temperature of about 800-1100° C. and a second temperature of about 1400° C. to 2500° C. Each heating operation is of about one second, and each cooling operation is of about one second. Inductive coupling of the induction coil(s) to the susceptor is used for each heating operation. Convective heat removal by cooling gas dispersion of the gas nozzle(s) is used as the primary method for each cooling operation.

One embodiment is a semiconductor wafer annealing apparatus. The apparatus as a susceptor, at least one induction coil, and at least one gas nozzle. The susceptor has a first surface and opposed second surface. The susceptor is arranged to seat a semiconductor wafer with a first face of the wafer exposed and a second face of the wafer seated in thermal contact with the first surface of the susceptor. The induction coil(s) is arranged to receive the susceptor seating the wafer with the induction coil(s) in wraparound arrangement to the susceptor and the seated wafer. At least one gas nozzle is arranged to disperse cooling gas to the susceptor and the seated wafer as a susceptor and wafer assembly, with the susceptor and wafer assembly received within the induction coil(s). The apparatus is operable at least to perform multiple cycles of one second heating and one second cooling of the wafer, to anneal the wafer, cycling the wafer to and from a first temperature of about 800-1100° C. and a second temperature of about 1400° C. to 2500° C. Such operation is through inductive coupling of the induction coil(s) to the susceptor and thermal conduction of the susceptor to the seated wafer for each heating of the wafer. Such operation is through at least convective heat removal by cooling gas dispersion of the gas nozzle(s) and the thermal conduction of the susceptor to the seated wafer for each cooling of the wafer.

One embodiment is a method of annealing a semiconductor wafer. The method includes holding the wafer by a susceptor, with a first face of the wafer exposed and a second face of the wafer in thermal contact with a first surface of the susceptor, as a susceptor and wafer assembly. The method includes positioning the susceptor holding the wafer within at least one induction coil. The induction coil(s) is in wraparound arrangement to the susceptor holding the wafer. At least one gas nozzle is arranged to disperse cooling gas to the susceptor and wafer assembly. In the method, multiple rapid cycles of heating and cooling the wafer are performed, to anneal the wafer. Each heating operation of about one second duration heats the wafer from a first temperature of about 800-1100° C. to a second temperature of about 1400° C. to 2500° C. through inductive coupling of the induction coil(s) to the susceptor and thermal conduction of the susceptor to the seated wafer. Each cooling operation of about one second duration cools the wafer from about the second temperature to about the first temperature through at least convective heat removal by cooling gas dispersion of the gas nozzle(s) and further thermal conduction of the susceptor from the seated wafer.

Other aspects and advantages of the embodiments will become apparent from the following detailed description taken in conjunction with the accompanying drawings which illustrate, by way of example, the principles of the described embodiments.

### BRIEF DESCRIPTION OF THE DRAWINGS

The described embodiments and the advantages thereof may best be understood by reference to the following description taken in conjunction with the accompanying drawings. These drawings in no way limit any changes in form and detail that may be made to the described embodiments by one skilled in the art without departing from the spirit and scope of the described embodiments.

FIG. 1A depicts some embodiments of an apparatus for rapid-cycle high-temperature heating and cooling a workpiece, which can be used for annealing a semiconductor wafer.

FIG. 1B depicts a further embodiment of an apparatus, with a nozzle positioned to direct cooling gas flow to one face or surface of the susceptor.

FIG. 1C depicts a further embodiment of an apparatus, with a nozzle positioned to direct cooling gas flow to one face or surface of the wafer, in the wafer and susceptor assembly.

FIG. 1D depicts a further embodiment of an apparatus, with a nozzle positioned to direct cooling gas flow to one face or surface of the wafer, in the wafer and susceptor assembly, and another nozzle positioned to direct cooling gas flow to an opposed face or surface of the susceptor.

FIG. 2 further depicts some embodiments of the apparatus of FIG. 1A, with the vessel illustrated in see-through form to make visible embodiments of a coil for inductive heating, gas nozzles for dispersing cooling gas, and further components.

FIG. 3A is a side view of some embodiments of a susceptor for the apparatus of FIGS. 1A-D and 2, with a semiconductor wafer showing fitment to the susceptor. Other variations can be placed within the central region for other shaped wafers or materials.

FIG. 3B is an overhead view of the susceptor embodiments of FIG. 3A. Also, other variations can be done, like square wafer(s), etc.

FIG. 3C is a perspective view of the susceptor embodiments of FIG. 3A. Also, other variations can be done, like square wafer(s), etc.

FIG. 4A is a perspective view of some embodiments of a nozzle suitable for the apparatus of FIGS. 1A and 2.

FIG. 4B is a perspective view of a further embodiment of a nozzle suitable for the apparatus of FIGS. 1A and 2.

FIG. 4C is an overhead view of a different kind of nozzle that could be used instead of the one in 4A. Still further kinds of nozzles can be used.

FIG. 4D is a perspective is a perspective view of the nozzle in 4C that is also suitable for the apparatus of FIGS. 1A and 2.

FIG. 5 is a perspective view of some embodiments of a support bracket suitable for the apparatus of FIGS. 1A-D and 2. Other designs are possible, including supports that mount to the nozzles, and ones that mount to the chamber.

FIG. 6 is a flow diagram illustrating some embodiments of a method of operation of the apparatus of FIGS. 1A-D and 2 and variations thereof, for rapid-cycle high-temperature heating and cooling to anneal a semiconductor wafer or other suitable workpiece.

FIG. 7 is a perspective cutaway cross-section view of an embodiment depicting a substrate and susceptor assembly in relation to inlet nozzles and outlet nozzles.

FIG. 8 is a cutaway cross-section side view of an embodiment depicting a substrate and susceptor assembly in relation to an inlet nozzle and an outlet nozzle.

FIG. 9 is a perspective cutaway view of an embodiment depicting a chamber wall, an inlet nozzle and an outlet nozzle.

### DETAILED DESCRIPTION

Described herein are various embodiments of an apparatus and method of operation for rapid-cycle high-temperature heating and cooling of a workpiece, which can be applied for annealing a semiconductor wafer or other suitable workpiece. One technological problem presented, with technological solutions thereto, is how to achieve relatively even heating and relatively even cooling across a semiconductor wafer, at high temperatures for example heating and cooling to and from 800-1100° C. and 1400° C.-2500° C., i.e., heating from 800-1100° C. to 1400° C.-2500° C. and cooling from 1400° C.-2500° C. to 800-1100° C., in multiple rapid cycles of one second each direction, without destroying, damaging or reducing lifespan of equipment or components thereof. Technological solutions disclosed herein, when applied for rapid thermal annealing of semiconductors, may provide breakthrough advances in power electronics to deliver high voltage switching. The techniques disclosed herein are not limited to any particular semiconductors but can include semiconductors such as elementary, binary, tertiary, and quaternary alloys of wide and ultra-wide band gap semiconductors. Embodiments described herein provide a tool that is capable of achieving goals here to for unmet by previous attempts. For example, previous attempts to retrofit many other devices failed to even get close to target temperatures, cooling rates, heating rates, uniformity, etc. Techniques explored for the heating aspect included resistance heating, oven/furnace heating, flame heating, laser heating, plasma heating, and finally induction heating. It was determined induction heating was the optimal way (especially with cost of equipment/parts, and daily use expenses in mind) to achieve the desired results, which then led to development of the specific apparatus embodiments described herein. Meetings with experts of various fields were held, with discussions of problems and the need to achieve heating results while within either an inert atmosphere or a vacuum (from low down to ultra-high vacuum) or high-pressure environment (from low to up to above 200 atm) all without contaminants and needs to allow for rapid on/off for the cooling cycle, optimal uniformity was also needed, not just as this would allow for the best properties for the annealing sample, but also to increase susceptor lifetime as it would reduce warping. Temperatures in and about this range, and time spans in and about this range, i.e., of the order of one second, are desirable for annealing gallium nitride wafers, and research achieved a 10 second heating cycle followed by 10 second cooling cycle, with benefits in quality. But, in colloquial terms, a one second heating and one second cooling in this temperature range and with energy levels required to produce such temperature changes is “not so easy”. It should be appreciated that an apparatus that is operable with the above temperatures, temperature ranges and cycle times is likely also operable with lower temperatures, narrower temperature ranges and possibly somewhat longer cycle times, but that the reverse is not necessarily so. Lower temperatures are easily achieved with more uniformity. Longer times allows for everything to be easier, etc.

Present embodiments of apparatus and method arose with considerable research and development, with consideration of materials, heating techniques and technology, cooling techniques and technology, and components applicable to each of these aspects. Further consideration was given to geometries, e.g., shapes of components, positioning of components and direction of outputs of components relative to workpiece, support of workpiece, heat energy transfer to and from workpiece, evenness of heating of workpiece, evenness of cooling of workpiece, rapidity of temperature change, energy levels, survivability of components in relatively harsh, extreme environment, design and manufacturability of components for production environment and lifespan, etc. Surveys were performed for various kinds of susceptor geometry and dimensions to get that exact smooth rectangular shape, including length, width, and radii exact dimensions. A survey was performed to determine the thickness of the susceptor. At the start of the project, it was assumed graphite would be best, but then determined that tungsten was better. Note that the susceptor is not limited to being tungsten or graphite and can be constructed with other metal types and groups including, but not limited to compound alloys. Thus, while certain embodiments are disclosed as being tungsten or graphite, it should be recognized that the susceptor can alternatively and additionally include these other metal types and groups. Types of heating investigated included flame, oven, resistive, inductive and laser. Types of cooling investigated included radiation, convection (both natural and forced) and conduction. Research explored using a fan-like system to cool it with air, a shutter system that would block out a heat lamp and provide cooling via radiation, bringing in a water-cooled surface to get near it for a second, and even moving it to a freezer for a second. For convection cooling, pressure vessels and forced gas were investigated, and determined to be optimum cooling mechanisms for achieving rapid uniform cooling as in present embodiments and variations thereof.

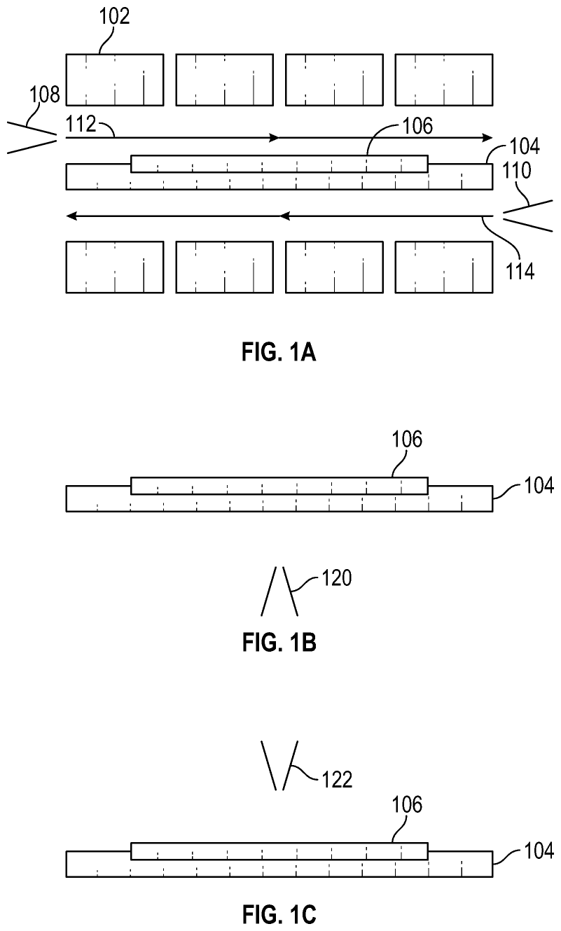

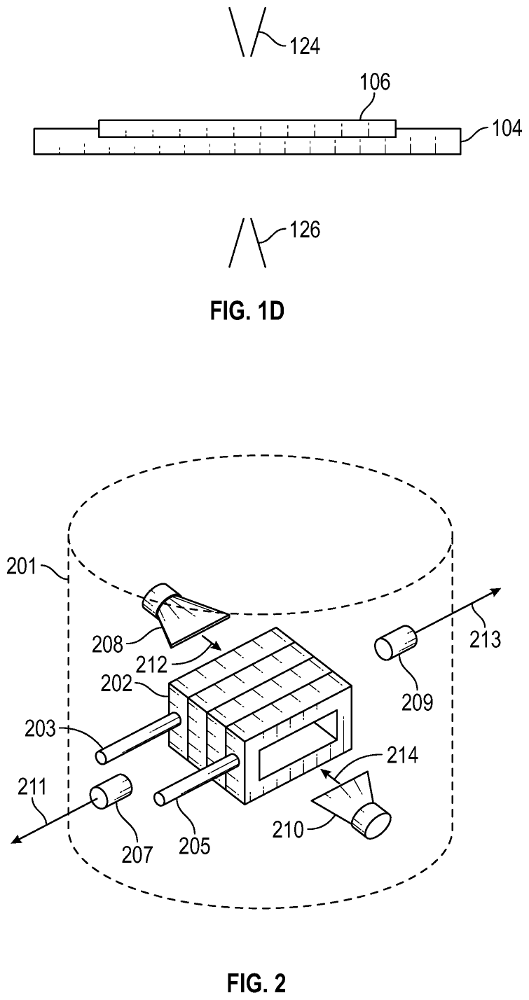

FIG. 1A depicts some embodiments of an apparatus for rapid-cycle high-temperature heating and cooling a workpiece, which can be used for annealing a semiconductor wafer 106. In use, the semiconductor wafer 106 (or other suitable workpiece) is seated on or otherwise held by a susceptor 104, for both heating and cooling, in rapid cycles. Note that while some embodiments are disclosed as used for annealing semiconductors, the techniques disclosed herein can be used for annealing other materials such as, for example, but not limited to, ferroelectric and/or ferromagnetic materials.

The susceptor 104 holds the wafer 106 within an induction coil 102. The apparatus causes application of inductive coupling of the induction coil 102 to the susceptor 104, and thermal conduction of heat from the susceptor 104 to the wafer 106, to rapidly heat the susceptor 104 and the wafer 106. Some embodiments have four coils 102, others can have multiple other turn-based designs based on needed specification, as the induction coil, which could also be termed a four turn or five turn induction coil. However, other numbers of coils can be used. Induction coils may be ganged in parallel or series in various embodiments and be considered a single coil or multiple adjacent coils. In some embodiments, the power supply for the five turn induction coil 102 has a requirement of 0-500 kHz, 0-300 kW, with voltages and amperages in the multi thousands at such high energy rates, which is sufficient with the induction coil 102, susceptor 104 and wafer 106 to heat the wafer 106 in the time needed to achieve the desired annealing properties. Note that the embodiments disclosed herein are not limited to use with a five turn inductor coil and the five turn induction coil can be replaced with a different design.

With the assembly of susceptor 104 and wafer 106 remaining in place in the induction coil 102, the apparatus applies cooling gas distribution from nozzles 108 and 110, and thermal conduction of heat from the wafer 106 to the susceptor 104, to rapidly cool the susceptor 104 and the wafer 106. In some embodiments, one nozzle 108 directs and distributes cooling gas flow 112 over one face of the susceptor 104 and wafer 106 assembly, including directing cooling gas flow 112 over one face of the wafer 106 (upward facing in FIG. 1). One nozzle 110 directs and distributes cooling gas flow 114 over an opposed face or surface of the susceptor 104 (downward facing in FIG. 1), from an opposed direction relative to the nozzle 108, the induction coil 102 and the received assembly of susceptor 104 and wafer 106. That is, in some embodiments, the cooling gas flows 112 and 114 are directed from opposite sides and to opposite faces or surfaces of the susceptor 104 and wafer 106 assembly, to effectively, evenly and rapidly cool the susceptor 104 and wafer 106 assembly and thus the wafer 106. In some embodiments, cooling gas flow can be of multiple rates, anything from letting the wafer cool via the high pressure environment or blasting large amounts of cooling gas (such as 300 SLM), this value can be determined either experimentally or via simulation that will achieve the users desired flow rate to sufficient to cool the wafer 106 from the high end annealing temperature to the low end annealing temperature within the necessary time frame. Both high velocity and high volume of gas flow are considered advantageous in achieving this temperature change at this rate or time span. Offset nozzles, e.g., at staggered elevation relative to the susceptor 104 and wafer 106 assembly, are believed to produce cooling flows that do not impede one another and contribute to fast cooling rate and low temperature gradient across the workpiece and susceptor. Radiation may play a role in cooling; however convection is believed the dominant heat transfer mode in cooling for these examples, and roughly 10 times higher than radiation in some embodiments.

FIG. 1B depicts a further embodiment of an apparatus, with a nozzle 120 positioned to direct cooling gas flow to one face or surface of the susceptor 104. In this embodiment, the nozzle 120 is positioned below or beneath the susceptor 104 and wafer 106 assembly, and the nozzle 120 is aimed at the bottom or lower face or surface of the susceptor 104. Thermal properties, e.g., thermal conductivity, thermal contact, of the susceptor 104 support rapid and even cooling of the susceptor 104 and wafer 106.

FIG. 1C depicts a further embodiment of an apparatus, with a nozzle 122 positioned to direct cooling gas flow to one face or surface of the wafer 106, in the wafer 106 and susceptor 104 assembly. In this embodiment, the nozzle 122 is positioned above the susceptor 104 and wafer 106 assembly, and the nozzle 122 is aimed at the upper face or surface of the wafer 106, which is in thermal contact to the upper face or surface of the susceptor 104.

FIG. 1D depicts a further embodiment of an apparatus, with a nozzle 124 positioned to direct cooling gas flow to one face or surface of the wafer 106, in the wafer 106 and susceptor 104 assembly, and another nozzle 126 positioned to direct cooling gas flow to an opposed face or surface of the susceptor 104. In this embodiment, the nozzle 124 is positioned above the susceptor 104 and wafer 106 assembly, aimed at the upper face or surface of the wafer 106, and another nozzle 126 is positioned below or beneath the susceptor 104 and wafer 106 assembly and aimed at the bottom or lower face or surface of the susceptor 104.

Still further embodiments may be devised, for example using a pancake coil for inductive heating, or other induction coil(s) determined by a user's heating requirement. In still further embodiments, laser heating is used with or without a viewport.

FIG. 2 further depicts an embodiment of the apparatus of FIG. 1A, with the vessel 201 illustrated in see-through form to make visible embodiments of a coil 202 for inductive heating, gas nozzles 208 and 210 for dispersing cooling gas, and further components. The vessel 201 encloses a chamber, in which the induction coil 202 is positioned, for example with suitable mounting (not shown, but readily devised) ready to receive the susceptor 104 and wafer 106 (see FIG. 1A). In some embodiments, the chamber is an inert environment capable of both ultra-low vacuum and high pressure. The induction coil 202 is depicted as four adjacent, rectangular coils, but other shapes and numbers of coils could be used in some other embodiments, for example for other shapes or dimensions of workpieces. Various fittings for the vessel 201, such as, for example, but not limited to, seals, clamps, viewport, gas and electrical lines, etc. are not shown but readily devised. Cooling gas nozzles 208, 210 are positioned to direct cooling gas flows 212 and 214 to respective surfaces of the susceptor 104 and wafer 106 as depicted in FIG. 1A, or in variations positioned as in FIGS. 1B-D, etc. In some embodiments, the gas nozzles 208 and 210 are as close as about 2 inches from the susceptor and wafer assembly when in place for processing, and the gas nozzles do not reach an excessive, damaging temperature. In some embodiments, gas outlets 207 and 209 are intended for connection to gas handling equipment, such as pumps, to direct gas outflows 211 and 213 removing spent cooling gas (from gas flows 212 and 214) from the chamber. In various embodiments, spent cooling gas may be exhausted, compressed for storage and reuse, or cooled and recirculated. Use of a vessel 201, with an enclosed chamber, may allow heating or cooling operations to run at ambient or atmospheric pressure, under a vacuum, or even up to a maximum pressure rating for the chamber in various embodiments.

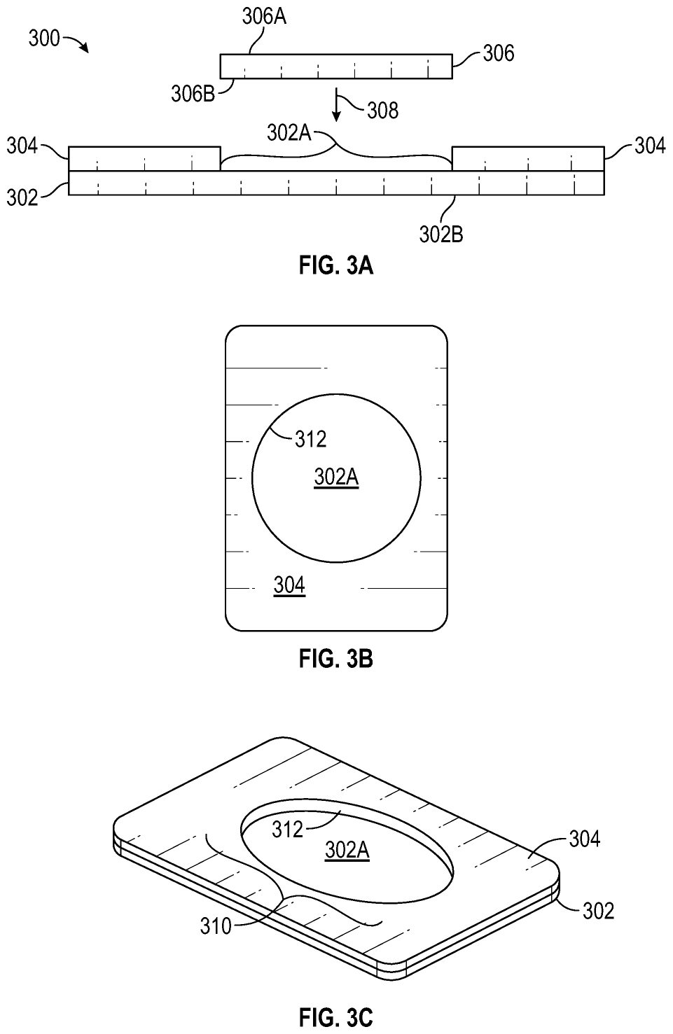

FIG. 3A is a side view of some embodiments of a susceptor that includes bottom susceptor 302 and the top susceptor 304 for the apparatus of FIGS. 1A-D and 2, with a semiconductor wafer 306 showing fitment to the bottom susceptor 302 and top susceptor 304. In some embodiments, the susceptor is composed of the bottom susceptor 302, made of tungsten, and the top susceptor 304 is made of boron nitride, which has thermal conductivity similar to the wafer, thus keeping the tungsten surface a uniform temperature and further improving uniformity for the heating and cooling. Graphite or other induction coupled material may be used in further embodiments. The two different materials can be fastened, clamped together, or otherwise held together in various ways. In one embodiment, the different materials of the susceptor are clamped together via supports that hang from the coils that anchor them down. It is possible thermal transfer for heating could be further improved upon without the top boron nitride susceptor, but the top boron nitride susceptor, in addition to adding uniformity during cooling, also is there to keep the wafer from flying off in some embodiments. The top boron nitride susceptor has the added benefit of having approximately the same thermal conduction as the wafer so the tungsten underneath should not warp too much. In research, multiple designs were tried, from having a pocket in tungsten (which didn't work well) to making the susceptor all tungsten, which was way too hard to cool. Present embodiments provide the best solution from research and development. But variations are contemplated and herein described. Embodiments can use graphite as another susceptor, really any great conductive material for the bottom piece, and any stable ceramic for the top piece. Both materials couple well for inductive heating by the induction coil 102. Other materials may be used in various embodiments. An aperture, or through hole (see FIG. 3C), in the top susceptor 304 is dimensioned to fit or receive the wafer 306, so that the susceptor (or susceptor assembly) formed by assembling the bottom susceptor 302 and the top susceptor 304 has a recess or pocket that exposes a portion 302A of a face of the bottom susceptor 302 to receive the wafer 306. The wafer 306 is seated into the recess or pocket of the bottom susceptor 302 and the top susceptor 304 by moving the wafer 306 in a direction 308, with one face 306A of the wafer 306 remaining exposed, and the opposed face 306B of the wafer 306 making thermal contact to the portion 302A of the bottom susceptor 302. With the bottom susceptor 302 and top susceptor 304 holding or seating the wafer 306, the susceptor and wafer assembly 300 is ready for insertion into the induction coil 102 (see FIGS. 1A and 2). In one embodiment, the boron nitride piece has a hole cut out for the wafer. The wafer sits in this hole and will not fly out of the pocket. In one embodiment, the boron nitride and tungsten are clamped together so they will not fly out or otherwise move around. Thus the assembly stays together. In further embodiments, screws or fasteners could be used for such an assembly, as could further means.

Inductive heating of the bottom susceptor 302 and the top susceptor 304 and thermal transfer through the large contact area to the wafer 306 can take place, and convective cooling of the bottom susceptor 302 and the top susceptor 304 and the wafer 306 can take place through cooling gas distribution over the exposed surfaces of the assembly 300, including the exposed face 306A of the wafer 306 and an opposed service 302B of the bottom susceptor 302. Evenness of thermal transfer, heat distribution and resultant temperature across the workpiece is assisted by the large thermal contact of the wafer 306 and the bottom susceptor 302.

FIG. 3B is an overhead view of the susceptor embodiment of FIG. 3A. Here, the aperture 312 or through hole through the top susceptor 304 exposes the portion 302A of the bottom susceptor 302, providing a seat for holding the wafer 306 (not shown in FIG. 3B).

FIG. 3C is a perspective view of the susceptor embodiment of FIG. 3A. The recess 310, or pocket in the bottom susceptor 302 and the top susceptor 304 is visible with a wall as formed by the aperture 312 of the top susceptor 304, and with the exposed portion 302A of the bottom susceptor 302 as a floor of the recess 310. In some embodiments, the recess 310 is symmetric, and dimensioned to uniformly seat the wafer 306 flush with the corresponding upper surface of the top susceptor 304. Further embodiments could have unequal or angled seating of the wafer, for example with one side flush and the other raised, but the symmetric, flush seating is preferred and believed advantageous in restraining the wafer 306 and avoiding wafer blowouts (e.g., from cooling gas flow).

Susceptor deformation is to be avoided in embodiments, since this may lead to lower lifecycle, obstruction of cooling flow, the wafer no longer sitting securely in the susceptor, the susceptor falling out of a support, or short-circuit of an induction coil. A high temperature gradient across the susceptor's cross-section could lead to severe deformation and warping of the susceptor. A too-deep wafer pocket can result in poor temperature uniformity between the susceptor top and bottom surfaces due to electrically thin parameters of the material making up the wafer pocket.

In some embodiments, the susceptor includes a horizontal, flat wafer pocket to fit a 4 inch or 100.5 mm diameter wafer and a wafer carrier that should fit inside a specific coil, 1¼ mm thickness, while making sure that the pocket is deep enough to restrain a wafer but not too deep for top surface to reach required temperature and while providing temperature uniformity. Too thin material for a floor of a wafer pocket may be electrically “thin” from the standpoint of coupling to the induction coil, and/or may provide poor temperature uniformity in the pocket and is thus not recommended.

In some embodiments, the susceptor is designed to avoid and/or reduce concerns involving one or more of: an angled design could lead to lower temperature uniformity in a pocket, additional force on supports due to unequal center of gravity and the trailing edge of the pocket may not be deep enough to restrain a wafer. In some embodiments, the susceptor is designed for a 4 inch wafer and acts as a 1½ mm thick wafer carrier. Tungsten deforms very heavily if it has uneven temperature gradient across its thickness. This is the case for all materials that cause materials that are flat sheets to look like potato chips but is especially true for Tungsten, and even more so thin Tungsten.

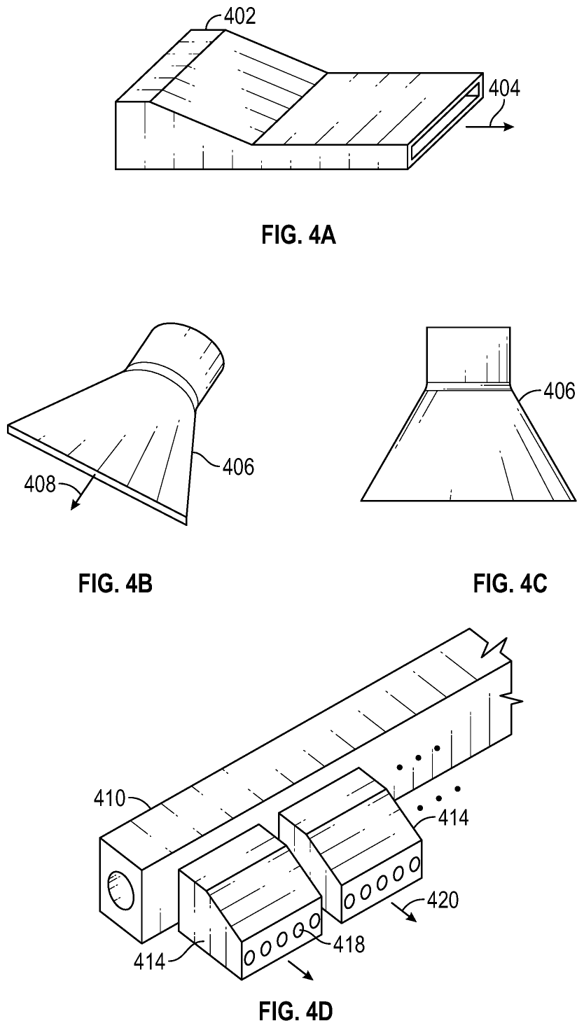

FIG. 4A is a perspective view of some embodiments of a nozzle 402 suitable for the apparatus of FIGS. 1A and 2. Desirably, these embodiments, and some other embodiments, of nozzles produce a flat, high-speed and high-volume gas flow 404, and such nozzles may be termed an air blade in recognition of the shape of the gas flow 404 thereby produced, which resembles a blade made of air or gas. It should be appreciated that an air blade is used with various gases and not restricted to atmospheric air. Suitable cooling gases include air, oxygen, hydrogen, nitrogen, helium, argon, and others are readily employed. In some embodiments, the cooling gas is room temperature nitrogen. In the embodiment in FIG. 4A, the nozzle 402 has a single outlet with a rectangular shape, which could have squared or rounded corners and could have multiple outlets (or orifices) in further embodiments (e.g., see FIG. 4D). In some embodiments, the nozzle 402 can be placed in various locations. For example, in some embodiments where only a top coil or bottom coil as needed, the nozzle 402 (or variation thereof) may be placed to face the wafer and susceptor assembly directly from underneath or above (e.g., opposing the coil), for uniform cooling temperature gradient across the surface of the susceptor and wafer assembly.

FIG. 4B is a perspective view of some other embodiments of a nozzle 406 suitable for the apparatus of FIGS. 1A and 2. In the direction of airflow, the shape of the nozzle 406 changes from gas inlet that is circular in cross-section, for example to connect to a gas line, pipe or circular cross-section conduit, to a broadened, flattened cross-section and gas outlet, for example to produce a broad or wide, flat gas flow 404. The gas outlet could have a single orifice or have multiple orifices in variations. For example, each of multiple orifices, or each of multiple gas outlets, can be placed on different planes.

FIG. 4C is an overhead view of the nozzle 406 of FIG. 4B. The expanding profile from top to bottom or inlet to outlet may be curved or angular and may be optimized for laminar airflow at specified flow rates.

FIG. 4D is a perspective view of a further embodiment of a nozzle suitable for the apparatus of FIGS. 1A and 2. A nozzle feed pipe 410, which may also be a plenum, feeds cooling gas to multiple nozzles 414, for example a gang of four or other number, which collectively produce a broad, flat (e.g., blade-shaped) airflow 420. This example illustrates a nozzle made of nozzles, or a compound nozzle. In some embodiments, each nozzle 414 of the compound nozzle has multiple outlets 418 or orifices, and further embodiments could have fewer or more outlets, including the possibility of a single outlet per nozzle 414 (see, e.g., FIGS. 4A and 4B).

Various further shapes and types of nozzles and airflows are contemplated. It is believed the air blade is advantageous for evenness of cooling the essentially flat surfaces of various plates as workpieces, including the example susceptor and wafer assemblies described herein. Stainless steel is a suitable material for making nozzles, and other materials may be devised. In some embodiments, custom nozzles are made once a particular process is determined as ideal or optimum.

In some embodiments, the nozzle material and placement, applicable to various embodiments of nozzles and variations thereof, can include conductive nozzles that are placed outside of the region of inductive coils and/or non-conductive nozzles placed far closer. Such conductive nozzles have been found to not get hotter than 250° C. while being 2 inches from a focused induction coil. In some embodiments, believed optimal, nozzles should maintain nozzle tip cross-section dimensions, have attachability, take up limited space in the system and do not make loading of a wafer difficult, while providing uniform flow exiting the nozzle tip cross-section.

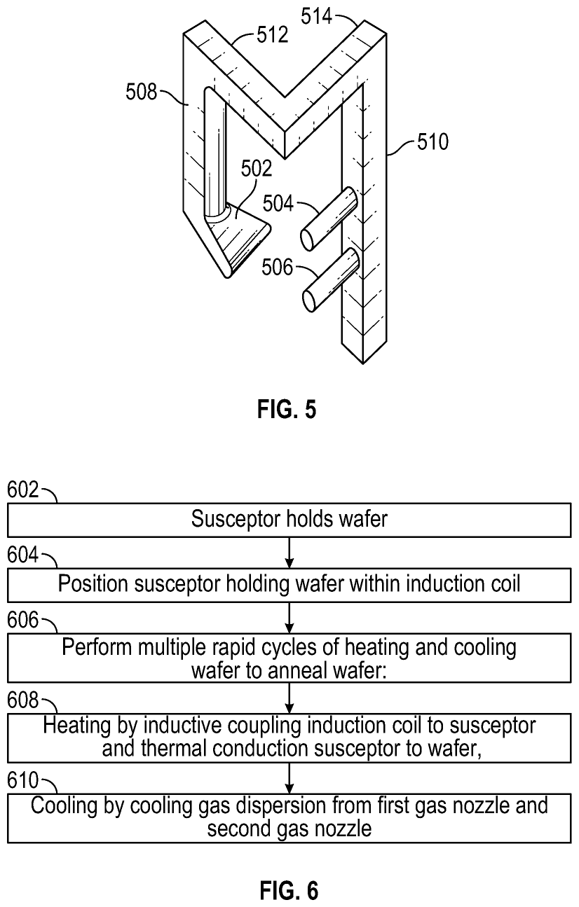

FIG. 5 is a perspective view of an embodiment of a support bracket suitable for the apparatus of FIGS. 1A-D and 2. There could be, for example, four of these support brackets in an apparatus, one to support each corner of a susceptor and wafer assembly. Other brackets and/or other supports may be used in further embodiments. In one embodiment, the support bracket is made of ceramic, to withstand high temperatures and avoid coupling to the induction coil. In one embodiment, the support bracket is made of alumina. This example support bracket has a vertical bracket arm 508 terminated by or at least supporting end piece 502 or end shelf, upon which a corner of the susceptor and wafer assembly can be slid horizontally until it bumps into this end piece and rests against it. The support bracket has another vertical bracket arm 510, from which two support pins 504 and 506 project, which can support an edge portion of a susceptor and wafer assembly using minimal physical contact. The vertical bracket arms 508 and 510 are shown connected, for example by joiner arms 512 and 514 which could be permanently joined or separable in various embodiments, e.g., for assembly and/or maintenance.

In some embodiments, the wafer carrier support, such as those applicable to the support bracket in FIG. 5 and variations thereof, have minimal thermal impact with susceptor and coils, restrain all degrees of freedom, have rounded edges that minimize flow disturbance, utilize coil geometry, and have a simple assembly with various possible configurations.

FIG. 6 is a flow diagram illustrating an embodiment of a method of operation of the apparatus of FIGS. 1A-D and 2 and variations thereof, for rapid-cycle high-temperature heating and cooling to anneal a semiconductor wafer or other suitable workpiece. It should be appreciated that further equipment, such as a vessel with a chamber and various fittings, processor control, controllable valves, motors, transport mechanism, gas supplies, power supply, etc., can be used in implementation specific embodiments of the apparatus described herein, which in turn can be used for implementing and practicing embodiments of the method. Furthermore, it should be appreciated that while some embodiments of the method are disclosed for use in annealing semiconductors, the techniques disclosed herein can be used for annealing other materials such as, for example, but not limited to, ferroelectric and/or ferromagnetic materials.

In an action 602, a susceptor holds a wafer. Specifically, this may be a semiconductor wafer, and more specifically a gallium nitride wafer which may have an implanted defect. More generally, the susceptor holds a workpiece. In one embodiment a surface of the wafer is in thermal contact with a surface of the susceptor, for conductive heat transfer in both heating and cooling the wafer, and another surface of the wafer and another surface of the susceptor are exposed for convection cooling. In one embodiment, the wafer is seated to a tungsten plate. In one embodiment, the wafer is seated in a recess of the susceptor.

In an action 604 the susceptor holding the wafer is positioned within the induction coil. This positioning is for inductive coupling of the induction coil to the susceptor and also for positioning the susceptor and wafer assembly relative to the first gas nozzle and the second gas nozzle. This may be the end of the loading process.

In an action 606, multiple rapid cycles of heating and cooling the wafer are performed, to anneal the wafer. Heating is by inductive coupling the induction coil to the susceptor and thermal conduction of the susceptor to the wafer. Cooling is by cooling gas dispersion from the first gas nozzle and the second gas nozzle. Cooling may also include radiation (e.g., radiative cooling). In some embodiments, the gas nozzles are air blades. In some embodiments, various types of gas nozzles are used, and may be custom nozzles. In some embodiments, cooling gas dispersion is directed from opposed directions and to opposed sides, surfaces or faces of the susceptor and wafer assembly. In various embodiments, a heating operation heats the wafer from about 800-1100° C. to about 1400° C. or up to about 2500° C. (e.g., ±100° C.) in about one second (e.g., ½ second to 2 seconds) and a cooling operation cools the wafer from about 1400° C. or up to about 2500° C. to about 800-1100° C. in about one second (e.g., with similar range variation). Tuning for cycling between whatever temperatures are needed to within the time that is needed is applied to the power to the coil, and the flow rate out the nozzles. One embodiment has a heating rate of 500° C. per second, and one embodiment has a cooling rate of 800° C. per second.

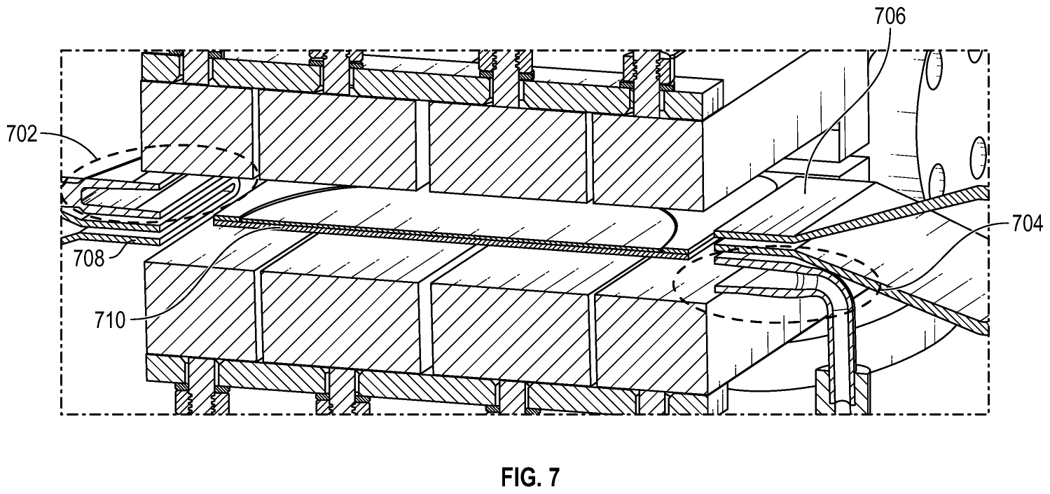

In order to facilitate removal of gas(es) from the apparatus, some embodiments feature outlet nozzles. These are nozzle-like features that are at opposite ends and help maintain smooth velocity across the wafer carrier or other substrate and susceptor assembly, so that flows do not impede. In some embodiments, the use of outlet nozzles may make cooling more efficient. In some embodiments, outlets can be removed and/or added depending on apparatus user preferences and/or test results, etc. FIGS. 7-9 depicts various embodiments of outlet nozzles, and variations thereof may be developed in keeping with the teachings herein.

FIG. 7 is a perspective cutaway cross-section view of an embodiment depicting a substrate and susceptor assembly 710 in relation to inlet nozzles 706, 708 and outlet nozzles 702, 704. In this and some other embodiments, one outlet nozzle 702 is opposite one inlet nozzle 706, so as to exhaust cooling gas therefrom. Another outlet nozzle 704 is opposite another inlet nozzle 708, so as to exhaust cooling gas therefrom. That is, a given outlet nozzle is paired with a given inlet nozzle, these being on opposed ends of the substrate and susceptor assembly 710 to manage cooling gas flow across one face of the substrate and susceptor assembly 710. One paired inlet nozzle and outlet nozzle manages cooling gas flow across the respective face of the substrate and susceptor assembly 710, and another paired inlet nozzle and outlet nozzle manages cooling gas flow across an opposed face of the substrate and susceptor assembly 710. Cooling gas flow is right to left in the diagram for the inlet nozzle 706 paired to the outlet nozzle 702 and the upper face of the substrate and susceptor assembly 710 and left to right for the inlet nozzle 708 paired to the outlet nozzle 704 and lower face of the substrate and susceptor assembly 710.

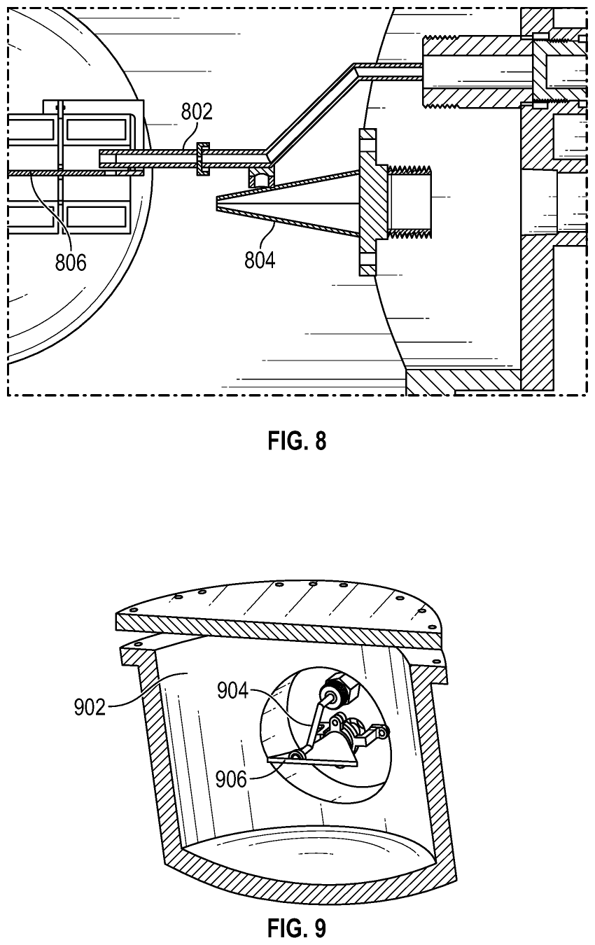

FIG. 8 is a cutaway cross-section side view of an embodiment depicting a substrate and susceptor assembly 806 in relation to an inlet nozzle 804 and an outlet nozzle 802. In this embodiment, the inlet nozzle 804 provides cooling gas flow across the lower face of the substrate and susceptor assembly 806, and the outlet nozzle 802 removes cooling gas flow across the upper face of the substrate and susceptor assembly 806.

FIG. 9 is a perspective cutaway view of an embodiment depicting a chamber wall 902, an inlet nozzle 906 and an outlet nozzle 904. The mouth of the inlet nozzle 906 and the mouth of the outlet nozzle 904 are immediately adjacent, with the two components attached to each other at those respective extremities.

In some embodiments, outlet nozzles act like to pressure relief valves that keep the vessel in a desired pressure range so that nitrogen or other cooling gas being added via the cooling cycle is expelled. Outlet nozzles can act like relief valves, in some embodiments, even when they are also functioning to smooth the flow from the opposite inlet nozzles. For example, gas flow may be diverted from the outlet nozzles to relief valves, in embodiments.

Detailed illustrative embodiments are disclosed herein. However, specific functional details disclosed herein are merely representative for purposes of describing embodiments. Embodiments may, however, be embodied in many alternate forms and should not be construed as limited to only the embodiments set forth herein. It should be appreciated that descriptions of direction and orientation are for convenience of interpretation, and the apparatus is not limited as to orientation with respect to gravity. In other words, the apparatus could be mounted upside down, right side up, diagonally, vertically, horizontally, etc., and the descriptions of direction and orientation are relative to portions of the apparatus itself, and not absolute.

It should be understood that although the terms first, second, etc. may be used herein to describe various steps or calculations, these steps or calculations should not be limited by these terms. These terms are only used to distinguish one step or calculation from another. For example, a first calculation could be termed a second calculation, and, similarly, a second step could be termed a first step, without departing from the scope of this disclosure. As used herein, the term “and/or” and the “/” symbol includes any and all combinations of one or more of the associated listed items.

As used herein, the singular forms “a”, “an” and “the” are intended to include the plural forms as well, unless the context clearly indicates otherwise. It will be further understood that the terms “comprises”, “comprising”, “includes”, and/or “including”, when used herein, specify the presence of stated features, integers, steps, operations, elements, and/or components, but do not preclude the presence or addition of one or more other features, integers, steps, operations, elements, components, and/or groups thereof. Therefore, the terminology used herein is for the purpose of describing particular embodiments only and is not intended to be limiting.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Although the method operations were described in a specific order, it should be understood that other operations may be performed in between described operations, described operations may be adjusted so that they occur at slightly different times or the described operations may be distributed in a system which allows the occurrence of the processing operations at various intervals associated with the processing.

Various units, circuits, or other components may be described or claimed as “configured to” or “configurable to” perform a task or tasks. In such contexts, the phrase “configured to” or “configurable to” is used to connote structure by indicating that the units/circuits/components include structure (e.g., circuitry) that performs the task or tasks during operation. As such, the unit/circuit/component can be said to be configured to perform the task, or configurable to perform the task, even when the specified unit/circuit/component is not currently operational (e.g., is not on). The units/circuits/components used with the “configured to” or “configurable to” language include hardware—for example, circuits, memory storing program instructions executable to implement the operation, etc. Reciting that a unit/circuit/component is “configured to” perform one or more tasks, or is “configurable to” perform one or more tasks, is expressly intended not to invoke 35 U.S.C. 112, sixth paragraph, for that unit/circuit/component. Additionally, “configured to” or “configurable to” can include generic structure (e.g., generic circuitry) that is manipulated by software and/or firmware (e.g., an FPGA or a general-purpose processor executing software) to operate in manner that is capable of performing the task(s) at issue. “Configured to” may also include adapting a manufacturing process (e.g., a semiconductor fabrication facility) to fabricate devices (e.g., integrated circuits) that are adapted to implement or perform one or more tasks. “Configurable to” is expressly intended not to apply to blank media, an unprogrammed processor or unprogrammed generic computer, or an unprogrammed programmable logic device, programmable gate array, or other unprogrammed device, unless accompanied by programmed media that confers the ability to the unprogrammed device to be configured to perform the disclosed function(s).

The foregoing description, for the purpose of explanation, has been described with reference to specific embodiments. However, the illustrative discussions above are not intended to be exhaustive or to limit the invention to the precise forms disclosed. Many modifications and variations are possible in view of the above teachings. The embodiments were chosen and described in order to best explain the principles of the embodiments and its practical applications, to thereby enable others skilled in the art to best utilize the embodiments and various modifications as may be suited to the particular use contemplated. Accordingly, the present embodiments are to be considered as illustrative and not restrictive, and the invention is not to be limited to the details given herein but may be modified within the scope and equivalents of the appended claims.

What is claimed is:

1. An apparatus, comprising:
a susceptor having a first surface and opposed second surface, arranged to hold a workpiece with a first face of the workpiece exposed and a second face of the workpiece in thermal contact with the first surface of the susceptor, as a susceptor and workpiece assembly;
at least one induction coil arranged to receive the susceptor holding the workpiece with the at least one induction coil in wraparound arrangement to the susceptor and workpiece assembly;
at least one gas nozzle arranged to disperse cooling gas to the susceptor and workpiece assembly; and
the apparatus operable to perform a sequence of cycles of heating and cooling operations on the susceptor and workpiece assembly, cycling the workpiece to and from a first temperature of about 800° C.-1100° C. and a second temperature of about 1400° C.-2500° C., each heating operation of about one second and each cooling operation of about one second, through inductive coupling of the at least one induction coil to the susceptor for each heating operation and through at least convective heat removal by cooling gas dispersion of the at least one gas nozzle for each cooling operation.

2. The apparatus of claim 1, wherein the at least one gas nozzle is arranged to disperse cooling gas to the first face of the workpiece.

3. The apparatus of claim 1, wherein the at least one gas nozzle is arranged to disperse cooling gas to the second surface of the susceptor.

4. The apparatus of claim 1, wherein the at least one gas nozzle comprises:
a first gas nozzle arranged to disperse cooling gas to the first face of the workpiece; and
a second gas nozzle arranged to disperse cooling gas to the second surface of the susceptor.

5. The apparatus of claim 1, wherein the at least one gas nozzle comprises an air blade.

6. The apparatus of claim 1, wherein the susceptor comprises a tungsten plate.

7. The apparatus of claim 1, wherein the susceptor comprises graphite.

8. The apparatus of claim 1, wherein the at least one induction coil comprises four or five coils.

9. The apparatus of claim 1, wherein the at least one induction coil comprises a pancake coil.

10. The apparatus of claim 1, wherein the susceptor includes a recess dimensioned to seat the workpiece.

11. The apparatus of claim 1, wherein the at least one nozzle comprises stainless steel.

12. The apparatus of claim 1, further comprising a vessel having a chamber, wherein the at least one nozzle comprises first and second nozzles in opposed arrangement relative to the chamber and the at least one induction coil.

13. The apparatus of claim 1, further comprising at least one outlet nozzle.

14. A semiconductor wafer annealing apparatus, comprising:
a susceptor having a first surface and opposed second surface, arranged to seat a semiconductor wafer with a first face of the wafer exposed and a second face of the wafer seated in thermal contact with the first surface of the susceptor;
at least one induction coil arranged to receive the susceptor seating the wafer with the at least one induction coil in wraparound arrangement to the susceptor and the seated wafer;
at least one gas nozzle arranged to disperse cooling gas to the susceptor and the seated wafer as a susceptor and wafer assembly, with the susceptor and wafer assembly received within the at least one induction coil; and
wherein the apparatus is operable at least to perform multiple cycles of one second heating and one second cooling of the wafer, to anneal the wafer, cycling the wafer to and from a first temperature of about 800° C.-1100° C. and a second temperature of about 1400° C.-2500° C., through inductive coupling of the at least one induction coil to the susceptor and thermal conduction of the susceptor to the seated wafer for each heating of the wafer and through at least convective heat removal by cooling gas dispersion of the at least one gas nozzle and the thermal conduction of the susceptor to the seated wafer for each cooling of the wafer.

15. The semiconductor wafer annealing apparatus of claim 14, wherein the at least one gas nozzle comprises an air blade.

16. The semiconductor wafer annealing apparatus of claim 14, wherein the susceptor comprises:
a tungsten plate having the second surface of the susceptor; and
a boron nitride top susceptor having an aperture exposing the first surface of the susceptor as a portion of the tungsten plate to which the semiconductor wafer is to seat.

17. The semiconductor wafer annealing apparatus of claim 14, wherein the at least one induction coil comprises four or five adjacent rectangular coils.

18. The semiconductor wafer annealing apparatus of claim 14, wherein the susceptor includes a symmetric recess dimensioned to seat the wafer.

19. The semiconductor wafer annealing apparatus of claim 14, wherein the at least one nozzle comprises a plurality of nozzles and comprises stainless steel.

20. The semiconductor wafer annealing apparatus of claim 14, further comprising a vessel having a chamber, wherein the at least one nozzle comprises first and second nozzles in opposed arrangement relative to the chamber, the at least one induction coil and operable positioning of the susceptor seating the wafer.

21. The semiconductor wafer annealing apparatus of claim 14, further comprising at least one outlet nozzle.

22. A method of annealing a semiconductor wafer, comprising:
holding the wafer by a susceptor, with a first face of the wafer exposed and a second face of the wafer in thermal contact with a first surface of the susceptor, as a susceptor and wafer assembly;
positioning the susceptor holding the wafer within at least one induction coil, with the at least one induction coil in wraparound arrangement to the susceptor holding the wafer, and with at least one gas nozzle arranged to disperse cooling gas to the susceptor and wafer assembly; and
performing multiple rapid cycles of heating and cooling the wafer, to anneal the wafer, comprising:
each heating operation of about one second duration heating the wafer from a first temperature of about 800° C.-1000° C. to a second temperature of about 1400° C.-2500° C. through inductive coupling of the at least one induction coil to the susceptor and thermal conduction of the susceptor to the seated wafer; and
each cooling operation of about one second duration cooling the wafer from about the second temperature to about the first temperature through at least convective heat removal by cooling gas dispersion of the at least one gas nozzle and further thermal conduction of the susceptor from the seated wafer.

23. The method of annealing a semiconductor wafer of claim 22, wherein the convective heat removal by cooling gas dispersion of the at least one gas nozzle comprises cooling gas dispersion through a first air blade and through a second air blade.

24. The method of annealing a semiconductor wafer of claim 22, wherein holding the wafer by the susceptor comprises seating the susceptor to a tungsten or graphite plate.

25. The method of annealing a semiconductor wafer of claim 22, wherein inductive coupling of the at least one induction coil to the susceptor comprises inductive coupling of four or five coils to the susceptor.

26. The method of annealing a semiconductor wafer of claim 22, wherein holding the wafer by the susceptor includes seating the wafer in a recess of the susceptor.

27. The method of annealing a semiconductor wafer of claim 22, wherein positioning the susceptor holding the wafer within the at least one induction coil comprises positioning the susceptor holding the wafer within a chamber of a vessel having the at least one gas nozzle as first and second nozzles in opposed arrangement relative to the chamber and the at least one induction coil.

28. The method of annealing a semiconductor wafer of claim 22, wherein positioning the susceptor holding the wafer within the at least one induction coil comprises positioning the susceptor holding the wafer within a chamber of a vessel having the at least one gas nozzle arranged to disperse cooling gas to the first face of the wafer.

29. The method of annealing a semiconductor wafer of claim 22, wherein positioning the susceptor holding the wafer within the at least one induction coil comprises positioning the susceptor holding the wafer within a chamber of a vessel having the at least one gas nozzle arranged to disperse cooling gas to a second surface of the susceptor.

30. The method of annealing a semiconductor wafer of claim 17, further comprising:
exhausting cooling gas through at least one outlet nozzle.
